(19) United States
(12) Patent Application Publication
(10) Pub. No.: US 2026/0218413 A1
(43) Pub. Date: Jul. 30, 2026

(54) SINGLE CRYSTAL DIAMOND

(71) Applicant: Element Six Technologies Limited, Didcot, Oxfordshire (GB)

(72) Inventor: Teodoro GRAZIOSI, Didcot, Oxfordshire (GB)

(21) Appl. No.: 19/142,053

(22) PCT Filed: Dec. 19, 2023
(86) PCT No.: PCT/EP2023/086593

§ 371 Date: Jun. 20, 2025

(30) Foreign Application Priority Data
Dec. 22, 2022 (GB) 2219497.1

(51) Int. Cl. C30B 25/16; C30B 25/18; C30B 25/20; C30B 29/04

(52) U.S. Cl. CPC C30B 25/16; C30B 25/186; C30B 25/20; C30B 29/04

(57) ABSTRACT

A method of measuring detectable features indicative of strain arising from subsurface damage below a surface of single crystal diamond having an area of at least 1 mm² is described. The method comprising using any of Raman microscopy to highlight a peak shift indicative of strain; and fluorescence imaging to highlight features associated with defects.

### FIELD OF THE INVENTION

The present invention relates to the field of single crystal diamonds, in particular single crystal diamonds with no detectable subsurface damage, and to methods of detecting subsurface damage in a single crystal diamond.

### BACKGROUND OF THE INVENTION

Subsurface damage in single crystal diamonds can have a large effect on the properties of the single crystal diamond. This is the case both for single crystal diamonds with no overgrowth, or for single crystal diamonds with an overgrown layer. For example, a high purity single crystal diamond may be overgrown with a thin layer of single crystal diamond that contains a higher concentration of nitrogen, which can be converted to NV centres. Such diamonds may be used as magnetic sensors capable of forming a magnetic image of a sample placed in contact or proximity with the high [NV⁻] layer, such as a semiconductor chip, a biological sample or a mineral sample. The magnetic image may be created, for example, by performing an Optically Detected Magnetic Resonance (ODMR) measurement of the diamond sensor in proximity/contact with the sample, then with an appropriately designed optics path and software it is possible to construct the image with spatially resolved magnetic measurements

Magnetic information detected by ODMR is contained in resonance dips measured in the optical domain, based on the Zeeman effect. When a magnetic bias field is applied, the m_s=±1 levels undergo Zeeman splitting, which can be detected by collecting the fluorescence spectrum. Given the typical strength of the signal in these types of applications, it is beneficial to use only a thin layer of fluorescing diamond to increase the spatial resolution. By using a bulk high-[NV⁻] diamond, at each pixel the signal at the detector will be the convolution of the signal from the portion of the material in close proximity to the sample (affected by the magnetic field we want to measure) and of the bulk of the material away from the sample (not affected by the field we want to measure), thus resulting in broadened resonance dips and a reduced contrast. The excited state spin Hamiltonian also depends on the local strain, and so local strain variations will cause an additional perturbation of the NV fluorescence which are not desirable.

The strain in the high-[NV⁻] layer can have multiple origins. Samples are grown on high purity substrates with as little nitrogen content as possible, such as those described in WO0196633 and WO0196634, that can have a high density of dislocations, which give rise to a propagation of these dislocations in the subsequently overgrown high-[NV] layer.

These features are clearly identifiable with a number of techniques and are also detectable in ODMR maps. Additionally, prior to overgrowth of the high [NV−] layer, the high purity substrate is typically processed, for example by polishing. This can induce subsurface damage in the high purity substrate which is subsequently transferred as strain into the high-[NV⁻] layer during the short etching and the growth.

### SUMMARY

It is desirable to have a non-destructive way to characterise subsurface damage in diamond. For example, where high-purity diamond is overgrown to form a high-[NV⁻] layer, the high-[NV⁻] layer typically takes on defects that propagate from the high-purity diamond substrate. Assessing the degree of subsurface damage in the high-purity diamond substrate in a non-destructive way would therefore facilitate deciding whether such a substrate is suitable for overgrowth.

According to a first aspect, there is provided a method of measuring detectable features indicative of strain arising from subsurface damage below a surface of single crystal diamond having an area of at least 1 mm², the method comprising using any of Raman microscopy to highlight a peak shift indicative of strain; and fluorescence imaging to highlight features associated with defects.

As an option, the method further comprises using Optically Detected Magnetic Resonance to measure features indicative of strain arising from subsurface damage to a depth of no more than 5 μm below the surface of the single crystal diamond over at least 50% of the area, for a single crystal diamond that comprises spin defects.

As an option, the method further comprises using Differential Image Contrast mode to measure features indicative of strain arising from subsurface damage to a depth of no more than 5 μm below the surface of the single crystal diamond, over at least 50% of the area, for a single crystal diamond that comprises a first layer and a second, overgrown, layer.

When using fluorescence imaging to highlight features associated with defects, the method optionally comprises applying a filter to a resultant image to highlight desired frequencies of fluorescence.

According to a second aspect, there is provided a method of manufacturing a composite single crystal diamond. The method comprises:
providing a single crystal diamond substrate having an area of at least 1 mm²;
measuring detectable features indicative of strain arising from subsurface damage below a surface of the single crystal diamond substrate diamond, the measuring comprising using any of Raman microscopy to highlight a peak shift indicative of strain; and fluorescence imaging to highlight features associated with defects;
homoepitaxially overgrowing a second layer of CVD single crystal diamond on the single crystal diamond substrate thereby forming a composite single crystal diamond comprising two layers in which the single crystal diamond substrate forms the first layer.

Using this method allows the subsurface damage of a single crystal diamond substrate to be assessed in a non-destructive way prior to subsequent overgrowth.

As an option, after providing the single crystal diamond substrate, the surface of the single crystal diamond substrate is processed using chemical mechanical polishing, CMP.

As an option, after providing the single crystal diamond substrate, the surface of the single crystal diamond substrate is processed using Scaife polishing. As a further option, the Scaife polishing uses 0 to 1 μm grit.

There is also described herein a single crystal diamond having a surface, wherein the surface has an area of at least 1 mm² and the surface displays no detectable features indicative of strain arising from subsurface damage to a depth of no more than 5 μm below the surface of the single crystal CVD diamond over at least 50% of the area. The detectable features indicative of strain are measured by either Raman microscopy or fluorescence imaging.

When using Raman microscopy on a single crystal sample, features indicative of strain include shifts in the wavelength of a Raman peak associated with diamond. This shows up as stress in a Raman stress map. When using fluorescence imaging, features indicative of strain can include fluorescence at particular wavelengths arising from other phases of carbon (e.g. sp2 carbon) that can arise from damage to the crystal or charge recombination happening at dislocations. These technique may be applied to any type of diamond, and are in particular suitable for single crystal diamond chemical vapour deposition, CVD, diamond.

Such single crystal diamond may comprise a first layer of single crystal diamond comprising less than 50 ppb nitrogen, and a second layer of single crystal diamond, wherein the second layer comprises at least 10 times the concentration of nitrogen-vacancy centres than the first layer, the second layer having a thickness of between 5 nm and 100 μm. This type of configuration is typical in some quantum applications where a thin layer of diamond containing NV centres is overgrown on a high purity diamond.

Where a second layer is present, the second layer may have a thickness selected from any of between 5 nm and 50 μm; between 5 nm and 20 μm; between 5 nm and 10 μm; and between 5 nm and 5 μm.

The surface may have been processed using chemical mechanical polishing, CMP. CMP polishing has been found to be particularly suitable to produce diamond with low or negligible subsurface damage.

Alternatively, the surface may have been processed using Scaife polishing, for example using 0 to 1 μm grit.

The surface may have an area selected from any of 2.25 mm², 4 mm², 9 mm² and 16 mm².

The surface may display no detectable strain arising from subsurface damage to a depth selected from any of no more than 3 μm, no more than 1 μm and no more than 0.5 μm.

The single crystal diamond may comprise a plurality of spin defects, and the surface displays no detectable features indicative of strain arising from subsurface damage to a depth of no more than 5 μm below the surface of the single crystal diamond over at least 50% of the area, the detectable features indicative of strain being further measured by Optically Detected Magnetic Resonance.

The single crystal diamond may comprise a first layer and a second, overgrown, layer, wherein the surface displays no detectable features indicative of strain arising from subsurface damage to a depth of no more than 5 μm below the surface of the single crystal diamond over at least 50% of the area, the detectable features indicative of strain being further measured by optical microscopy using a Differential Image Contrast mode.

### BRIEF DESCRIPTION OF THE DRAWINGS

Some embodiments of the invention will now be described by way of example only and with reference to the accompanying drawings, in which:

FIG. 1 illustrates schematically a side elevation view of an exemplary single crystal diamond comprising an overgrown layer;

FIG. 2 shows exemplary Raman maps over a 1 mm×1 mm area, in which FIG. 2a shows a stress map, FIG. 2b shows a FWHM map of the same scan, FIGS. 2c and 2d show stress data plotted in FIG. 2a differentiated along the two axes;

FIG. 3 shows Raman stress maps before and after thin layer overgrowth;

FIG. 4 illustrates schematically an effect of the pinhole setting in a Raman map;

FIG. 5 shows Raman stress maps compared to a DIC image of the sample of FIG. 2 after overgrowth;

FIG. 6a shows a fluorescence imaging image using a blue band-pass filter of a sample after overgrowth and irradiation and annealing to form NV centres, and FIG. 6b shows the same image using a blue channel split to highlight the signal from the strained regions;

FIG. 7a shows a high purity diamond substrate fluorescence imaging image taken with a green long-pass in which only the green channel of the RGB image is shown, FIG. 7b shows the same sample after overgrowth, with the blue channel of the RGB DV image shown, FIG. 7c shows an optical profilometer of the area in the centre of the plate illustrated by the dashed square in FIG. 7a, and FIG. 7d shows a Raman map of the same area in the centre of the plate; and

FIG. 8 shows an exemplary method of manufacturing a composite single crystal diamond.

### DETAILED DESCRIPTION

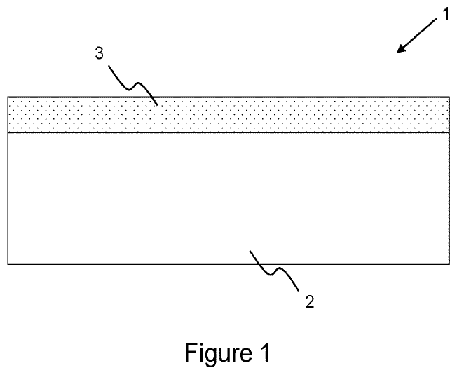

With reference to FIG. 1, a composite single crystal diamond 1 is illustrated that comprises a first layer 2 of high purity diamond with a low nitrogen content, such as that disclosed in WO0196633 and WO0196634, and an overgrown second layer 3 of high [N] diamond. As discussed above, when using the first layer 2 as a substrate for overgrowth of the second layer 3, it is useful to know if there is any detectable subsurface damage in the first layer 2. Currently, this is tested by destructive mechanisms such as revealing etches and so on. The suitability of a composite single crystal diamond 1 in terms of damage can only therefore be determined after the second layer 3 has been overgrown. A non-destructive way to assess subsurface damage in the first layer 2 prior to overgrowth of the second layer 3 would therefore be very desirable. Of course, there are other applications where an assessment of subsurface damage would be useful for other types of diamond including non-composite forms of diamond. For example, photonic structures can be created in high-purity diamond, but these can be susceptible to subsurface damage as it affects qubits in the top few microns. Subsurface damage is also a problem for detectors made using high-purity diamond, as it can act as a charge trap or current leakage path.

The inventors have devised ways to provide a non-destructive indication of subsurface damage in single crystal diamond material. Two exemplary ways are using Raman stress mapping and using fluorescence imaging. Furthermore, ways of achieving single crystal diamond material with very low subsurface damage are described.

Considering first Raman stress mapping, given the strong and narrow Raman peak of single crystal diamond, small variations in stress can be found by analysing a shift in the peak position.

For a processed surface, such as a surface that has undergone Scaife polishing, most of the area of the diamond will be under uniform stress, except for some isolated linear features where the polishing did not remove damage from previous processing step or introduced new subsurface damage in the surface.

Confocal Raman microscopy was tested to measure local stress in diamond plates. Single crystal diamond has a high Raman gain coefficient and produces a sharp Raman peak when excited with a laser. Given the sharpness of the peak, it can be used to measure several parameters that influence Raman scattering, such as temperature and, most importantly, strain. Raman has been used to measure subsurface damage in silicon, for example Xu et. al., “Topic Review: Application of Raman Spectroscopy Characterization in Micro/Nano-Machining”, Micromachines 9, 361 (2018) and Lu et. Al., “Non-Destructive Evaluation Methods for Subsurface Damage in Silicon Wafers: A Literature Review”, Int. J. Mach. Mach. Mater. 2, 18 (2007). However, these techniques measure phase changes occurring at a site of subsurface damage, whereas the present technique is concerned with a peak shift caused by stress around areas of subsurface damage.

A Horiba LabRAM confocal Raman microscope with a 514.5 nm laser was used to perform Raman microscopy on samples of single crystal diamond. A stress Raman gain coefficient depends on the stress state of the sample, as discussed in Prawer and Nemanich, “Raman Spectroscopy of Diamond and Doped Diamond”, Philos. Trans. R. Soc. Lond. Ser. Math. Phys. Eng. Sci. 362, 2537 (2004). It is difficult to deduce the stress state of the samples under test. Normally a thin film deposited onto a substrate is under a bi-axial stress state. We could imagine that this is a good approximation for the stress state of the high-[N] layer after deposition on the ELSC substrate, given the different nitrogen content of the two. The stress state of an as-processed high-purity plate is more difficult to assess, especially at the local level in proximity of scratches, pits, and subsurface damage. The choice of stress Raman gain coefficient to use is therefore difficult. A bi-axial stress state was assumed, with a stress Raman gain coefficient of 2.37 GPa/cm⁻¹. This means that the absolute value of the stress extracted is not accurate, but it can be used to infer if a pixel is in more compressive or more tensile stress compared to the rest of the plate. The analysis uses these results in a qualitative way only and Raman stress and Raman peak shift can be thought as the same entity. Nevertheless, regardless of the precise stress state, the stress Raman gain coefficient has an order of magnitude of GPa/cm⁻¹. Using a 514.5 nm laser and an 1800 grating, stress differences of the order of 10 MPa can be resolved.

To construct a Raman map, the laser is scanned across the surface of the sample. The high diamond Raman gain and the high laser power used means that 0.1 s is more than sufficient to acquire a spectrum with a high signal-to-noise ratio.

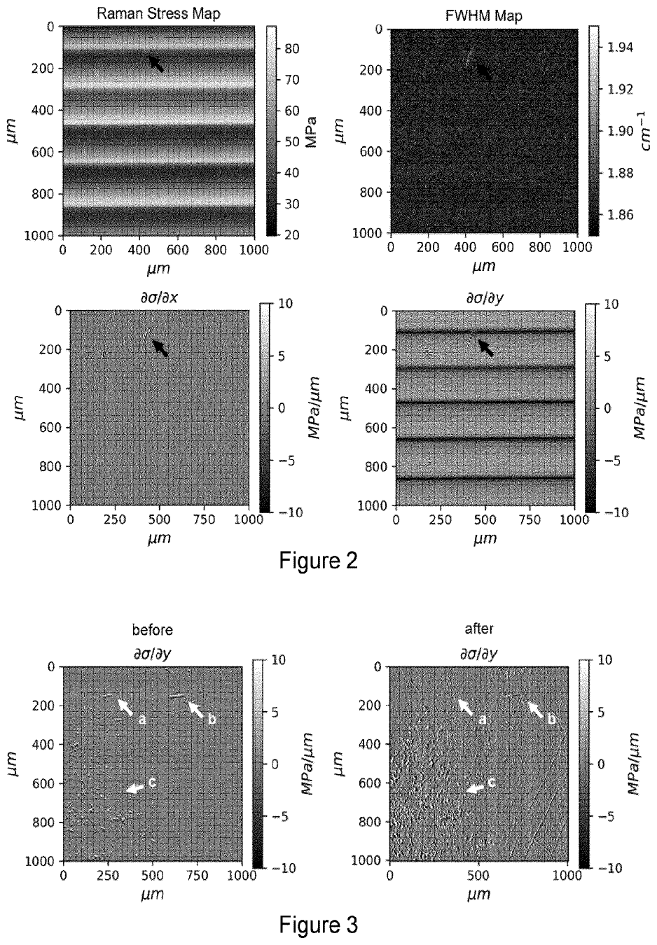

The scan records the Raman spectrum for each point of the map. The scan range was limited between 1310 and 1350 cm⁻¹. The dataset is exported as .txt file and then analysed with a python script which outputs several images. Each line of the .txt file stores the point coordinates and the counts for each wavelength bin. The script fits a pseudo-Voigt profile (a convolution of a Lorentzian and a Gaussian function) and uses the central position of the fit to calculate the stress as:

$${σ}_{Raman} = 2.37 G Pa cm \times ( {v}_{fit} - {v}_{unstressed} ) ,$$

where v_{fit} is the centre of the pseudo-Voigt peak and v_{unstressed} is the unstressed Raman peak (assumed to be 1332.3 cm⁻¹). The other fit parameter that will be used for plotting is the full-width at half-maximum (FWHM). The long scan time required creates another challenge for this measurement. FIG. 2a shows a typical stress (peak position) map. The most evident features are the horizontal lines going across the entire image. These are measurement artifacts caused by drift of the monochromator of the Horiba detector. When converted to stress, these artifacts mask the actual strain features and make assessment of the strain difficult.

There are several solutions to this problem, including a faster stage and electronics or the use of a reference source. When using a reference source, such as a noble gas lamp, the Raman peak shift would not be calculated on the absolute scale of the monochromator, but instead relative to one of those sharp emission lines, which would experience the same drift of the monochromator, thus ensuring a stable measurement.

Plotting the FWHM instead of the peak shift (stress) highlights the same strain features with greatly suppressed measurement artifacts (FIG. 2b). Alternatively, differentiating the stress map along the horizontal direction (FIG. 2c) will mask the measurement artifact while highlighting the pixels where a sharp change of stress occurs. Most, if not all, of the strain features we observe in these thin layer samples are sharp lines a few pixels wide, therefore they are not masked when differentiating the stress map along one image axis, except for features perfectly aligned with the differentiation direction. Plotting the FWHM or the differentiated stress does not allow for quantitative analysis, however, as discussed previously, this in not strictly necessary for the task of detecting subsurface damage if one is interested mostly in a qualitative rather than a quantitative measure of subsurface damage.

FIG. 3 shows a comparison between the same area of a high purity diamond sample before and after overgrowth of a high [NV] layer. An example of overgrowth is described in WO 2019145407. The same features are visible in both images, indicating that the technique can be used to identify the presence of subsurface damage in Scaife-polished high purity single crystal diamond plates. After growth, the features in the Raman stress map tend to increase in magnitude, increasing the signal from features that were barely detectable in the map taken before growth, possibly due to the generation of dislocation bundles in correspondence to the damaged areas.

The intensity of the features in the Raman map will depend on several factors, importantly the Raman acquisition settings, and the focus or sample tilt: if the damage layer is out of focus, the impact on the Raman spectra will be decreased.

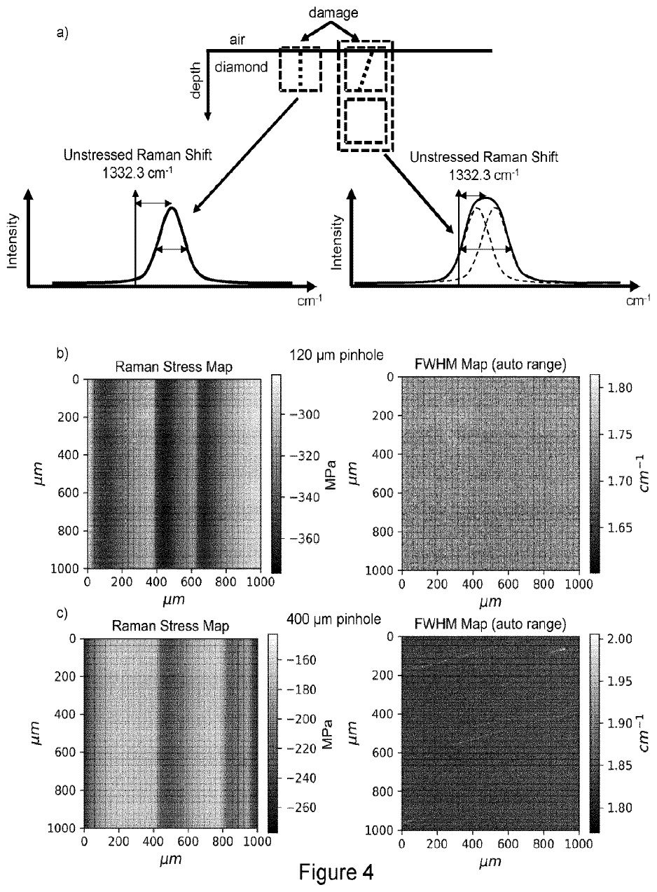

The skilled user can optimise other parameters to achieve a suitable signal-to-noise ratio, data acquisition time, measurement noise, and objective magnification. FIG. 4 illustrates schematically the effect of different pinhole sizes on Raman maps. The pinhole size in μm directly affects the sampling volume depth. With a 50× objective, a pinhole size of 120 μm and smaller will make the measurement confocal, with a sampling depth of approximately 3 μm. If the setting is larger than 120 μm, then the measurement will be less confocal and the signal at the detector will be a convolution of the signal from points at different distance from the surface.

When the measurement is confocal, the signal is be collected from the volume around the damaged layer. This results in generally sharper peaks that will give a clearer change in the peak position as the strain changes. The typical strain state of the samples tested here do not produce substantial broadening of the Raman peak, nor a splitting in multiple peaks, therefore the change in FWHM will be minimal between a strained and unstrained pixel. When the measurement is less confocal, the convolution of the signal produces a smaller apparent shift of the peak position, but a larger difference in FWHM. FIG. 4b and FIG. 4c show the trade-off between the two acquisition modes. A confocal setup will produce, generally, a more detailed image when plotting the Raman stress or peak position and a less detailed image when plotting the FWHM. The opposite is true for a less confocal setup. Given the presence of measurement artifacts in the stress map, the FWHM map is clearer, thus a less confocal setup would be preferred. The other option to remove the measurement artifact is to plot the differentiated stress as shown before, and in this case the confocal setup is preferred.

Microscopy is a quick technique and useful technique to assess the surface morphology, especially when used in differential interference contrast (DIC) mode. Unfortunately, the strain features are not visible on an as-processed high-purity diamond surface. We can normally identify the Scaife polishing direction due to lines aligned to the plate diagonal, however those features do not match with strain features found in the Raman map, reinforcing the case for which the strain is caused by subsurface damage and dislocation bundles. Therefore, one can have a well processed high-purity diamond plate with respect to the roughness and aesthetic specs that yields a highly strained thin layer. This is an important point because often a good Scaife finish is associated with a damage-free surface, while this is not necessarily true.

DIC microscopy becomes more useful after overgrowth of another layer, when it can be used to identify areas of high strain. During etching, the regions with high subsurface damage are etched preferentially. The growth morphology on the damaged region is substantially different compared to the rest of the layer, allowing an easy identification with a moderately magnified microscope (a 5× or 10× objective is sufficient). Normally the growth parameters used result in a step or island surface. The regions with damage produce a strong discontinuity in the surface, appearing like scratches.

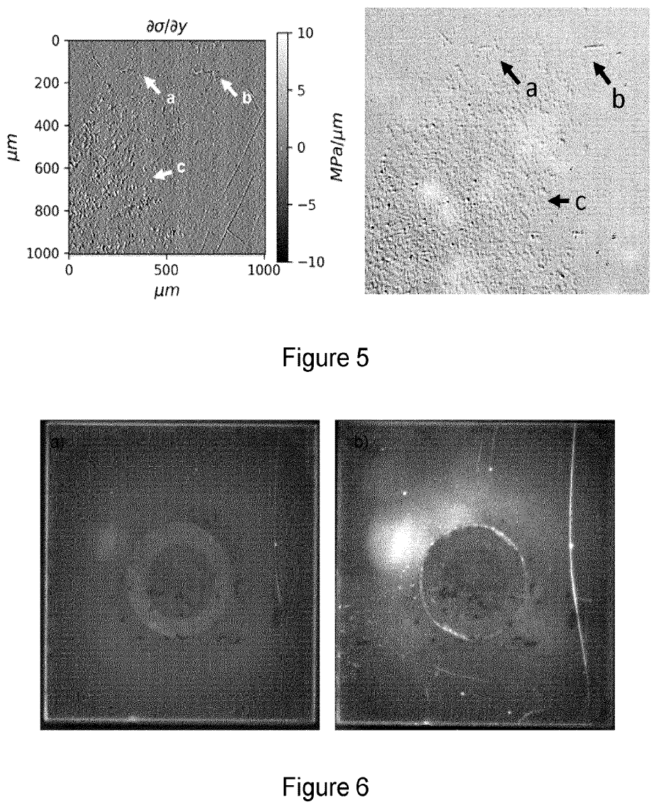

Identification is easy for a skilled person, and it can be enhanced with image postprocessing. FIG. 5 shows a comparison between a Raman stress map and a DIC image for the same sample. The microscopy images are taken with the Zeiss Axioscope in DIC mode with a 10× objective. The C2 polarizer is aligned to maximize the contrast, and since the relative orientation of features with the polarizer direction gives different contrast, multiple images with different polarizer orientation may be required to capture all strain features. To increase contrast, the DIC images can be postprocessed with ImageJ or Python by using edge detection algorithms. A direct correlation between strain features in Raman and DIC can be found, making DIC a good post-growth QC technique that is quicker than Raman stress mapping while offering a wide field of view.

Fluorescence imaging, such as that available using DiamondView™, is a good tool to quickly assess the sample at different stage of the process. For high purity diamond substrates with an overgrown high [NV] layer, it is useful to show the position of the high-[N] layer. When looking at DV images in correlation with ODMR and Raman stress maps, an interesting correlation was found. After growth, blue fluorescence is found in correspondence of areas of high strain, as shown in FIG. 6. Normally this signal would be masked by the much stronger orange fluorescence, especially when the sample was irradiated and annealed, but the blue fluorescence can be observed easily when using the blue band-pass filter with long integration. Given the high concentration of NV in the thin layer, the NV fluorescence is still dominant even with the blue band-pass filter, appearing as red-purple. To further highlight the blue component, it is useful to split the RGB channels and plot only the intensity of the B values. The origin of the blue fluorescence in this case can be easily explained. When growth occurs at the damaged region, the material deposited above the damage will have a higher dislocation density compared to the rest of the layer, causing band-A fluorescence when observed in DiamondView.

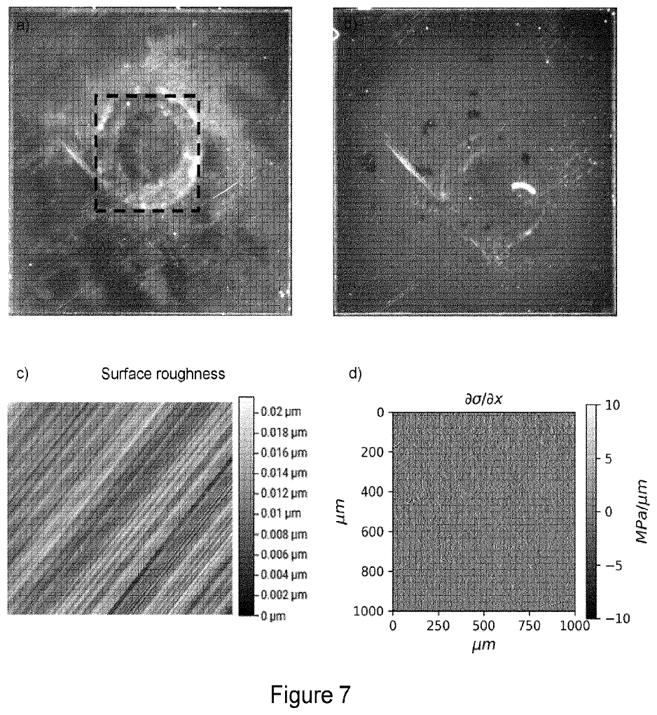

Together with the DIC inspection, DiamondView can give a quick qualitative assessment of the quality of the sample after growth. Interestingly, DiamondView is also an effective tool to assess the high purity diamond substrates before overgrowth. In this case, we can see two colours that appear, blue and turquoise-green. Blue is again related to dislocations and can also be found throughout the plate due to the typical dislocation density. Turquoise-green is more difficult to attribute, but whatever is the origin of the defects, the turquoise green fluorescence does correlate with regions of stress in Raman. In this case, it is the blue strong blue fluorescence that can mask the turquoise signal. To increase clarity, the green long-pass filter is used, and the G channel is separated from the RGB image. An image obtained using the blue band-pass filter and then splitting the B channel can also be used, but depending on the dislocation density, the dislocation luminescence may saturate the detector, masking the signal coming from the scratch-like features. An example is shown in FIG. 7a, and the corresponding sample after growth of the thin layer is shown in FIG. 7b. Most of the features in FIG. 7b can also be found in FIG. 7a, indicating a correlation between the turquoise fluorescence before growth and the blue fluorescence after growth.

FIG. 7c shows an optical profilometer of the area in the centre of the plate and FIG. 7d shows a Raman stress map of the area in the centre of the plate. In the profilometer image, there are lines aligned to the diagonal consistent with the Scaife process. In the stress map and the fluorescence image the features are not aligned to the diagonal suggesting that the signal comes from subsurface damage that is not visible with the optical profilometer. The Raman stress map offers more details compared to the fluorescence image due to the higher spatial resolution. FIGS. 7c and 7d are taken on the same area of the plate and are displayed with roughly the same scale.

To show that the green-turquoise and Raman features (FIGS. 7a and 7d) are not a surface effect but do in fact arise from subsurface damage, it is useful to compare them with the surface roughness obtained with the optical profilometer image shown in FIG. 7c. In the latter case, there are linear features that are well aligned to the plate diagonal, consistent with the direction of the Scaife polishing. For the Raman and the fluorescence image, the features are not aligned to the diagonal, and no correspondence can be found with surface morphology. More details are available with Raman stress mapping, due to the higher lateral resolution offered by the technique and the 50× objective chosen, but DiamondView can be used to identify subsurface damage before growth with a fast and easy tool, offering a much faster turnaround compared to Raman stress mapping. The comparison of FIGS. 7a and 7b further demonstrate that DiamondView can be used in a predictive way to identify subsurface damage before growth. Some optimization can be made with the acquisition settings of the DiamondView to decrease the noise level and boost clarity. The skilled person can determine optimized acquisition settings in terms of gain, acquisition time and aperture. The precise value of the acquisition time depends on the use of a filter and weather there a predominant luminescence to filter out (like in the case for the post-growth analysis). For the as-processed substrate analysis the green filter could be used. Alternatively, the user may use the visible filter and then post-process the image by selecting only the green colour channel.

Single crystal diamond with low subsurface damage can be prepared in various ways. It has been found that Scaife polishing using 0-1 μm grits is suitable for thin layers, but CMP polishing can also lead to samples with no detectable features indicative of strain arising from subsurface damage.

Results were obtained on high-purity diamond substrates with a standard Scaife finish and subsequently overgrown with a high [N] layer. Fluorescence imaging before and after overgrowth did not highlight any particular sign of damage, but when analysing the growth surface with DIC some short (<0.5 mm) features can be often found. This highlights the limit of using fluorescence imaging to detect subsurface damage of low intensity covering a limited are of the plate, mostly because of the low signal to noise of the turquoise-green luminescence and the presence of a much stronger band-A luminescence. It should be noted that such regions of high strain occupy a limited portion of the plate area.

When CMP polishing high purity diamond prior to overgrowth of a high [N] layer, both Raman and fluorescence imaging show a complete elimination of pre-existing subsurface damage following 50 hours of CMP polishing, and after growth the surface morphology does not highlight any damaged region.

Inductively couple plasma reactive ion etching (ICP-RIE), such as that disclosed in WO 2008/090511, to treat the surface of the high purity diamond prior to overgrowth of a high [N] layer also resulted in reliably low subsurface damage.

Several characterization methods were developed to assess the subsurface damage of high purity diamond plates prior to overgrowth. Such plates are typically not controlled for subsurface damage but only for dimensions and surface roughness. Since the damage is subsurface, DIC and profilometry are unable to detect it, and destructive methods such as oxygen etching were used to reveal the damage. Raman stress mapping and fluorescence imaging can effectively detect subsurface damage non-destructively. Moreover, since they do not rely on particular colour centres (such as NV) like ODMR mapping, they can be used on a wide range of samples, including high purity diamond. The two methods are complementary, with Raman stress mapping capable of higher resolution and showing more details but limited to small portion of the sample, and fluorescence imaging being more suitable for a lower resolution and quicker assessment of subsurface over a larger area.

Several growth runs were performed both to test the characterization techniques and to find an optimized process route to obtain a low subsurface damage substrate. ICP-RIE, chemical-mechanical polishing (CMP), and 0-1 μm Scaife polishing can process the substrate with low (or no) subsurface damage. In all cases scratch-like strain features were absent before and after growth.

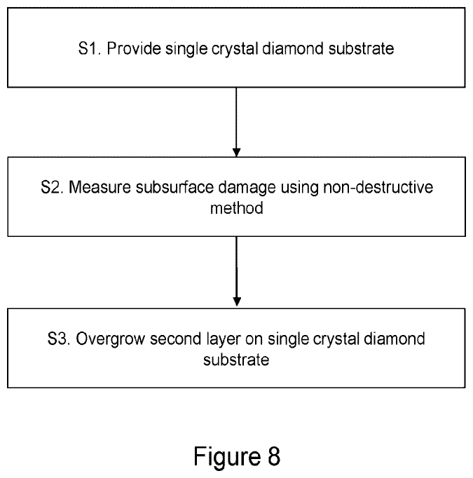

Turning now to FIG. 8, there is shown a flow diagram setting out exemplary steps for manufacturing a composite single crystal diamond. The following numbering corresponds to that of FIG. 8:
S1. A single crystal diamond substrate is provided that has an area of at least 1 mm². The surface may be processed to reduce subsurface damage. Exemplary ways of processing, as described above, include CMP, Scaife polishing (for example using 0-1 μm grit) and ICP-RIE.
S2. Detectable features indicative of strain arising from subsurface damage below a surface of the single crystal diamond substrate diamond are measured using either of Raman microscopy to highlight a peak shift indicative of strain or fluorescence imaging to highlight features associated with defects. Other techniques may also be used, such as DIC and ODMR. This acts as a quality control step. If subsurface damage is detected, then the substrate may not be suitable for use as a substrate for further overgrowth of diamond or may require further processing to remove subsurface damage.
S3. As an optional step, if the diamond substrate is to be overgrown, then a second layer of CVD single crystal diamond is overgrown on the single crystal diamond substrate thereby forming a composite single crystal diamond comprising two layers in which the single crystal diamond substrate forms the first layer.

While this invention has been particularly shown and described with reference to embodiments, it will be understood by those skilled in the art that various changes in form and detail may be made without departing from the scope of the invention as defined by the appended claims.

1. A method of measuring detectable features indicative of strain arising from subsurface damage below a surface of single crystal diamond having an area of at least 1 mm², the method comprising using any of Raman microscopy to highlight a peak shift indicative of strain; and fluorescence imaging to highlight features associated with defects.

2. The method according to claim 1, further comprising using Optically Detected Magnetic Resonance to measure features indicative of strain arising from subsurface damage to a depth of no more than 5 μm below the surface of the single crystal diamond over at least 50% of the area, for a single crystal diamond that comprises spin defects.

3. The method according to claim 1, further comprising using Differential Image Contrast mode to measure features indicative of strain arising from subsurface damage to a depth of no more than 5 μm below the surface of the single crystal diamond, over at least 50% of the area, for a single crystal diamond that comprises a first layer and a second, overgrown, layer.

4. The method according to claim 1, further comprising, when using fluorescence imaging to highlight features associated with defects, applying a filter to a resultant image to highlight desired frequencies of fluorescence.

5. A method of manufacturing a composite single crystal diamond, the method comprising:
providing a single crystal diamond substrate having an area of at least 1 mm²;
measuring detectable features indicative of strain arising from subsurface damage below a surface of the single crystal diamond substrate diamond, the measuring comprising using any of Raman microscopy to highlight a peak shift indicative of strain; and fluorescence imaging to highlight features associated with defects;
homoepitaxially overgrowing a second layer of CVD single crystal diamond on the single crystal diamond substrate thereby forming a composite single crystal diamond comprising two layers in which the single crystal diamond substrate forms the first layer.

6. The method according to claim 5, further comprising, after providing the single crystal diamond substrate, processing the surface of the single crystal diamond substrate using chemical mechanical polishing, CMP.

7. The method according to claim 5, further comprising, after providing the single crystal diamond substrate, processing the surface of the single crystal diamond substrate using Scaife polishing.

8. The method according to claim 7, further comprising Scaife polishing using 0 to 1 μm grit.
